(19) United States
(12) Patent Application Publication
(10) Pub. No.: US 2019/0317226 A1
(43) Pub. Date: Oct. 17, 2019

(54) X-RAY SENSING DEVICE AND MANUFACTURING METHOD THEREOF

(71) Applicant: Silicon Optronics, Inc., Hsinchu (TW)

(72) Inventor: Chi-Hsing HSU, Hsinchu (TW)

(21) Appl. No.: 16/204,010

(22) Filed: Nov. 29, 2018

(30) Foreign Application Priority Data
Apr. 12, 2018 (TW) 107112576

(51) Int. Cl. G01T 1/20; H01L 27/146; H04N 5/32

(52) U.S. Cl. CPC G01T 1/2018; H01L 27/14663; H01L 27/14683; H01L 27/14636; H04N 5/32

(57) ABSTRACT

An X-ray sensing device is provided. The X-ray sensing device includes a substrate, a first material layer, a circuit element, a photoelectric sensing element and a columnar structure. The first material layer is disposed over the substrate. The circuit element is disposed at a bottom portion of the first material layer. The photoelectric sensing is element disposed over the circuit element. The columnar structure is correspondingly disposed over the photoelectric sensing element and is in contact with the photoelectric sensing element. The columnar structure includes a scintillator material. The X-ray sensing device further includes a pad disposed on a top surface or a bottom surface of the first material layer and is coupled to the circuit element.

### CROSS REFERENCE TO RELATED APPLICATIONS

This application claims priority of Taiwan Application No. 107112576, filed on Apr. 12, 2018, the entirety of which is incorporated by reference herein.

### BACKGROUND

### Technical Field

The disclosure relates to an X-ray sensing device and a manufacturing method thereof, and in particular it relates to an X-ray sensing device having a columnar scintillator.

### Description of the Related Art

X-rays are widely used in the digital age. Example range from non-destructive detection in industrial applications to non-invasive imagery in the medical field. X-rays are frequently used in biomedical research, disease diagnosis, baggage inspection, and forensic science. X-rays are becoming more common in daily life and in technological applications, and have become an indispensable tool for modem technology.

X-ray sensing devices can detect X-rays and convert them into electronic signals to generate digital images. In general, X-ray sensing devices can be classified as indirect conversion type or direct conversion type. An indirect X-ray sensing device converts X-ray photons into visible light photons by using a scintillator formed of an X-ray conversion material, and converts visible light photons into electrons by photoelectric coupling elements. In addition, the electronic signals are converted into digital images by a thin-film transistor (TFT) or a complementary metal oxide semiconductor (CMOS) and related electronic components. The direct conversion type X-ray sensing device converts X-ray photons directly into electron-hole pairs by using a scintillator, and then converts the electronic signals into digital images by TFT or CMOS and related electronic components.

In the structure of a conventional X-ray sensing device, a bulk of a scintillator or a plate of a scintillator are mostly used. However, the manufacturing cost of the scintillator having large dimensions is high, and the crystal growth process for a scintillator having large dimensions is also more time consuming. On the other hand, in some X-ray sensing devices, an adhesive layer has to be used between the scintillator and the pixel array substrate (for example, it may include a photoelectric coupling element, TFT or CMOS). However, the adhesive layer may cause a decrease in image resolution or crosstalk interference in the signals.

In addition, whether the X-ray conversion material can be applied to a large-dimension process and whether sufficient conversion efficiency can be provided in the large-dimension process to reduce the dose of X-ray irradiation are also problems that should be taken into consideration in the conventional process.

Accordingly, further simplification of the process for manufacturing X-ray sensing devices and improving their performance are still topics that the industry is devoted to researching.

### SUMMARY

In accordance with some embodiments, the present disclosure provides an X-ray sensing device. The X-ray sensing device includes a substrate, a first material layer, a circuit element, a photoelectric sensing element and a columnar structure. The first material layer is disposed over the substrate. The circuit element is disposed at a bottom portion of the first material layer. The photoelectric sensing is element disposed over the circuit element. The columnar structure is correspondingly disposed over the photoelectric sensing element and is in contact with the photoelectric sensing element. The columnar structure includes a scintillator material. The X-ray sensing device further includes a pad disposed on a top surface or a bottom surface of the first material layer and is coupled to the circuit element.

In accordance with some embodiments, the present disclosure provides an X-ray sensing device. The X-ray sensing device includes a substrate, a first material layer, a circuit element and a columnar structure. The first material layer is disposed over the substrate. The circuit element is disposed at a bottom portion of the first material layer. The columnar structure is disposed over the circuit element and is in contact with the circuit element. The columnar structure includes a scintillator material. The X-ray sensing device further includes a pad disposed on a top surface or a bottom surface of the first material layer and is coupled to the circuit element.

In accordance with some embodiments, the present disclosure provides a method for manufacturing an X-ray sensing device. The method includes providing a carrier substrate, forming a first material layer over the substrate, patterning the first material layer to form an opening that exposes a portion of the surface of the photoelectric sensing element, and filling a scintillator material in the opening to form a columnar structure. A circuit element is disposed at a bottom portion of the first material layer, and a photoelectric sensing element is disposed over the circuit element. In addition, the columnar structure is in contact with the photoelectric sensing element.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIGS. 1A-1D are cross-sectional views of an X-ray sensing device in the intermediate stages of the process for manufacturing the X-ray sensing device in accordance with some embodiments of the present disclosure;

FIG. 2 is a cross-sectional view of an X-ray sensing device in accordance with some embodiments of the present disclosure;

FIGS. 3A and 3B are cross-sectional views of an X-ray sensing device in the intermediate stages of the process for manufacturing the X-ray sensing device in accordance with some embodiments of the present disclosure;

FIG. 4 illustrates a diagram showing the electrical connection between an X-ray sensing device and an external circuit in accordance with some embodiments of the present disclosure;

FIG. 5 illustrates a diagram showing the electrical connection between an X-ray sensing device and an external circuit in accordance with some embodiments of the present disclosure.

### DETAILED DESCRIPTION

The X-ray sensing device of the present disclosure and the manufacturing method thereof are described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. In addition, in this specification, expressions such as “a first material layer disposed on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer.

In addition, in this specification, relative expressions are used. For example, “lower”, “bottom”, “higher” or “top” are used to describe the position of one element relative to another. It should be appreciated that if a device is flipped upside down, an element that is “lower” will become an element that is “higher”.

It should be understood that, although the terms “first”, “second”, “third” etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

It should be understood that this description of the exemplary embodiments is intended to be read in connection with the accompanying drawings, which are to be considered part of the entire written description. The drawings are not drawn to scale. In addition, structures and devices are shown schematically in order to simplify the drawing.

In accordance with some embodiments of the present disclosure, the X-ray sensing device is provided. The X-ray sensing device has the columnar structure containing the scintillator materials. The columnar structure is correspondingly disposed over the photoelectric sensing element and is in direct contact with the photoelectric sensing element or the circuit element. In such a configuration, the amount of scintillator materials can be saved, and the detective quantum efficiency (DQE) and resolution of imaging of the X-ray sensing devices can be improved. In addition, in accordance with some embodiments of the present disclosure, the X-ray sensing device is fabricated by simple semiconductor processes, and the fabricated columnar structure can be accurately aligned with the photoelectric sensing element or the circuit element. Accordingly, the process efficiency and product yield can be improved.

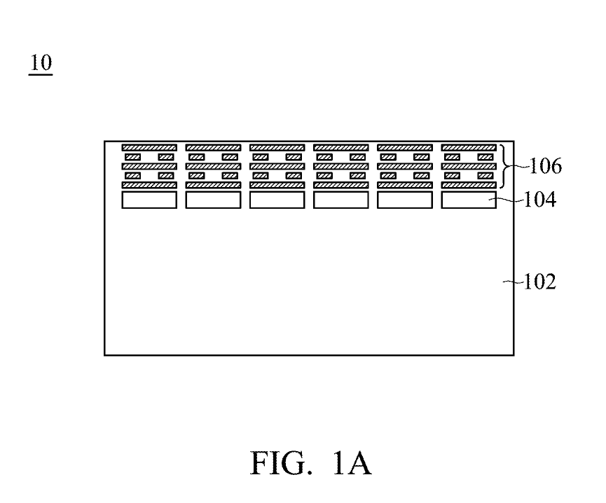

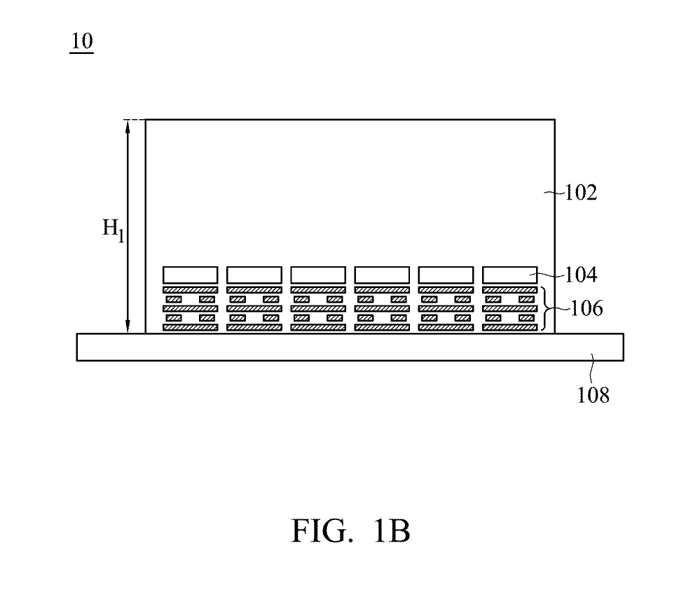

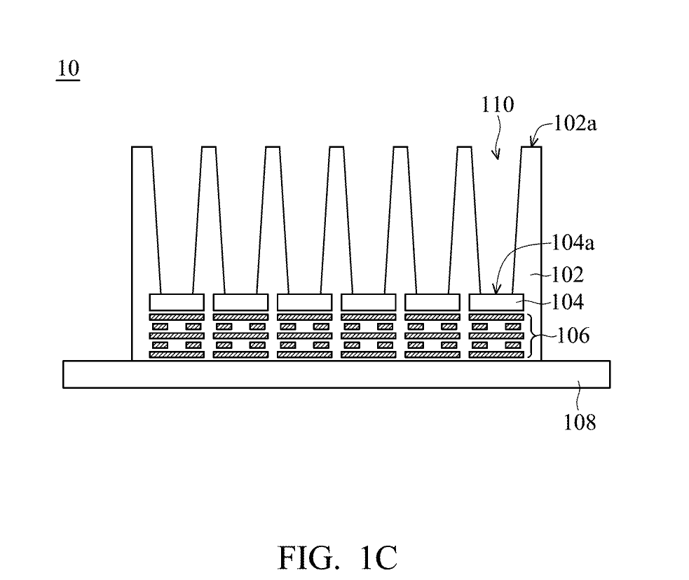

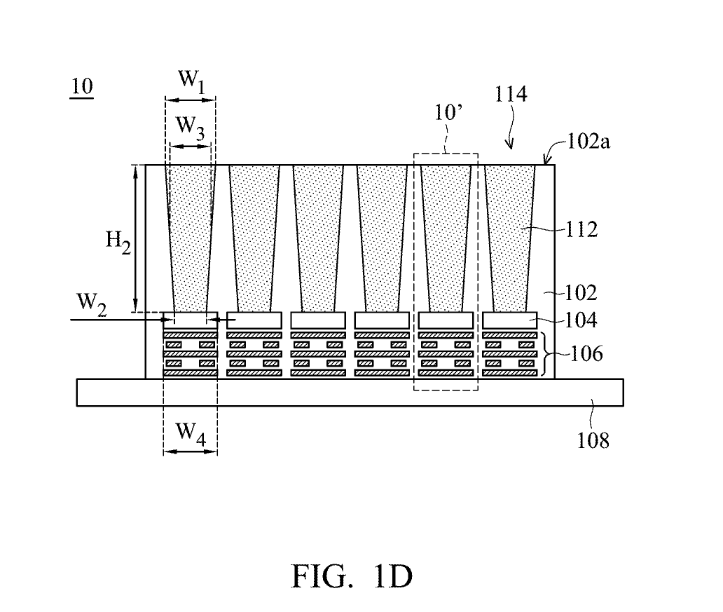

FIGS. 1A-1D are cross-sectional views of an X-ray sensing device 10 in the intermediate stages of the process for manufacturing the X-ray sensing device in accordance with some embodiments of the present disclosure. It should be understood that additional operations may be provided before, during, and/or after processes in the method for manufacturing the X-ray sensing device. In accordance with some embodiments, some of the operations described below may be replaced or eliminated. In accordance with some embodiments, additional features may be added to the X-ray sensing device 10. In accordance with some embodiments, some of the features described below may be replaced or eliminated.

First, referring to FIG. 1A, a first material layer 102 is provided. In some embodiments, a photoelectric sensing element 104 and a circuit element 106 may be disposed in the first material layer 102 in advance. The first material layer 102 may include silicon or glasses in accordance with some embodiments. In some embodiments, the first material layer 102 may be a wafer formed of semiconductor materials. For example, the first material layer 102 may include polysilicon, crystalline silicon, silicon germanium (SiGe), silicon carbide (SiC), or a combination thereof. The photoelectric sensing element 104 may convert visible photons into electrons. The photoelectric sensing element 104 may be any photoelectric coupling element (optical coupler). In some embodiments, the photoelectric sensing element 104 includes photodiode. In addition, the circuit element 106 may be used to provide electrical connections, receive electronics, store electronics, or process electronic signals and so on. For example, the circuit element 106 may be used to receive or store electrons from the photoelectric sensing element 104, or to process and read electronic signals generated thereby to generate digital images. In some embodiments, the circuit element 106 may have a thin-film transistor (TFT) structure or a complementary metal-oxide-semiconductor (CMOS) structure. In some embodiments, the circuit element 106 may include multiple metal layers to serve as the interconnect structure of X-ray sensing device 10. In some embodiments, the circuit element 106 may include an analog-to-digital converter, an image signal processor or a combination thereof.

Next, referring to FIG. 1B, the structure shown in FIG. 1A is flipped upside down and is disposed on the carrier substrate 108. As shown in FIG. 1B, the first material layer 102 is disposed over the carrier substrate 108. The circuit element 106 is disposed at the bottom portion of the first material layer 102, and the photoelectric sensing element 104 is disposed over the circuit element 106. The carrier substrate 108 may serve as a temporary support structure and it may be removed in the subsequent processes. In some embodiments, the carrier substrate 108 may be a silicon substrate, a glass substrate, a polymer substrate, a polymer-based composite substrate, or a combination thereof, but it is not limited thereto.

In addition, in accordance with some embodiments, a thinning process may be performed on the first material layer 102 that is formed on the carrier substrate 108. The first material layer 102 may be thinned to an appropriate thickness so that the subsequent processes (e.g., the patterning process) may be carried out successfully. In some embodiments, the thinned first material layer 102 has a first height H₁ ranging from about 50 μm to about 700 μm.

Next, referring to FIG. 1C, a patterning process is performed to remove a portion of the first material layer 102 to form an opening 110 that exposes a portion of the surface 104a of the photoelectric sensing element 104. The first opening 110 extends from the top surface 102a of the first material layer 102 to the portion of the surface 104a of the photoelectric sensing element 104. In some embodiments, one or more photolithography processes and etching processes are used to partially remove the first material layer 102. In some embodiments, the photolithography process may include photoresist coating (e.g., spin coating), soft baking, hard baking, mask aligning, exposure, post-exposure baking, developing the photoresist, rinsing, drying, or other suitable processes. In some embodiments, the etching process may include dry etching process, wet etching process or a combination thereof. For example, the dry etching process may include reactive ion etch (RIE), plasma etch and so on. In particular, the opening 110 that exposes the portion of the surface 104a of the photoelectric sensing element 104 is formed so that a columnar structure 114 that is subsequently filled in the opening 110 will be self-aligned with the photoelectric sensing element 104.

Next, referring to FIG. 1D, a scintillator material 112 is formed in the opening 110 to form the columnar structure 114. The columnar structure 114 is correspondingly disposed over the photoelectric sensing element 104 and is in contact with the photoelectric sensing element 104. Specifically, the columnar structure 114 is in direct contact with the photoelectric sensing element 104. The columnar structure 114 extends from the top surface 102a of the first material layer 102 to the top surface of the photoelectric sensing element 104 in accordance with some embodiments. The scintillator material 112 is in contact with the photoelectric sensing element 104 in accordance with some embodiments. The scintillator material 112 is formed of X-ray conversion materials that can convert X-rays into visible light or form electron-hole pairs. In this embodiment, the scintillation material 112 converts the received X-ray photons into visible light photons, and the generated visible light photons are transmitted to the photoelectric sensing element 104. The photoelectric sensing element 104 then converts the received visible light photons into electronic signals, such as current signals or voltage signals. Moreover, the photoelectric sensing element 104 may be coupled to the circuit element 106. The electronic signals generated by the photoelectric sensing element 104 may be transmitted to the circuit element 106 for processing to convert the electronic signals into digital images. In addition, the scintillating material 112 that is self-aligned with the photoelectric sensing element 104 may also ensure efficient transfer of the photons and electrons.

Moreover, the columnar structure 114 has a second height H₂. In some embodiments, the second height H₂ of the columnar structure 114 is in a range from about 50 μm to about 700 μm. In addition, the top portion of the columnar structure 114 has a first width W₁ and the bottom portion of the columnar structure 114 has a second width W₂. In some embodiments, the first width W₁ of the columnar structure 114 is different from the second width W₂ of the columnar structure 114. In some embodiments, the first width W₁ is greater than the second width W₂. In addition, the aspect ratio of the columnar structure 114 is in a range from about 1:1 to about 2:1 in accordance with some embodiments.

In some embodiments, the aspect ratio of the columnar structure 114 can be defined as the ratio of the second height H₂ of the columnar structure 114 to the first width W₁ of the top portion of the columnar structure 114, i.e. H₂/W₁. In other embodiments, the aspect ratio of the columnar structure 114 can be defined as the ratio of the second height H₂ of the columnar structure 114 to the second width W₂ of the bottom portion of the columnar structure 114, i.e. H₂/W₂. In other embodiments, the aspect ratio of the columnar structure 114 can be defined as the ratio of the second height H₂ of the columnar structure 114 to any width W₃ of the columnar structure 114, i.e. H₂/W₃. It should be noted that an appropriate range of the aspect ratio allows the columnar structure 114 to efficiently transmit visible light photons or electrons.

On the other hand, the photoelectric sensing element 104 has a fourth width W₄. The fourth width W₄ of the photoelectric sensing element 104 is greater than the second width W₂ of the columnar structure 114. In some embodiments, the fourth width W₄ of the photoelectric sensing element 104 is in a range from about 1 um to about 200 um.

As described above, the X-ray sensing device 10 as shown in FIG. 1D can be regarded as an indirect conversion type X-ray sensing device. In this embodiment, the scintillator material 112 may include CsI:Tl, CsI:Na, CsI, BGO(B₄G₃O₁₂), LYSO, YSO, Cd₂O₂S:Tb or a combination thereof. In some embodiments, the scintillator material 112 may be formed by a physical vapor deposition (PVD) process, a chemical vapor deposition (CVD) process, any other applicable method, or a combination thereof. For example, the physical vapor deposition may include a sputtering process, an evaporation process, or a pulsed laser deposition (PLD) process. The chemical vapor deposition process may include a low-pressure chemical vapor deposition (LPCVD) process, a low-temperature chemical vapor deposition (LTCVD) process, a rapid thermal chemical vapor deposition (RTCVD) process, a plasma enhanced chemical vapor deposition (PECVD) process, or an atomic layer deposition (ALD) process.

Furthermore, a second material layer (not illustrated) may be formed over the top surface 102a of the first material layer 102 in accordance with some embodiments. The second material layer may cover the first material layer 102 and be in contact with the first material layer 102 and the scintillating material 112. The second material layer may be used to further reduce crosstalk interference of the adjacent sensing elements or pixels. In some embodiments, the material of the second material layer may include tantalum oxides (TaO₂), copper (Cu), aluminum (Al) or a combination thereof.

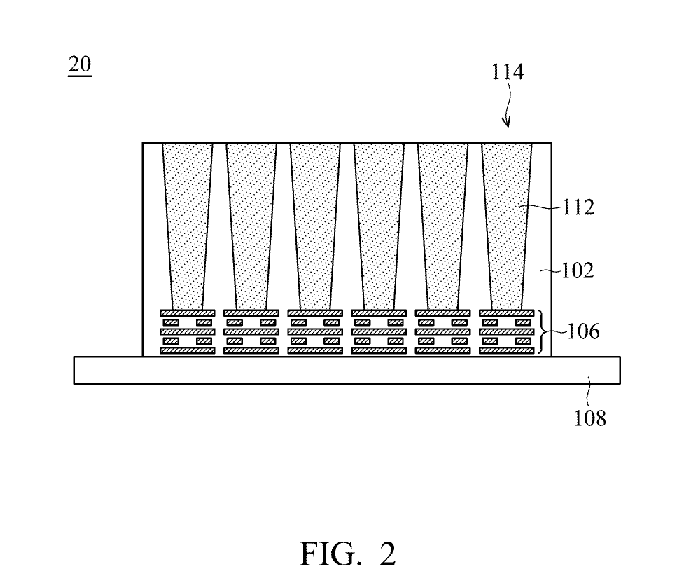

Referring to FIG. 2, which is a cross-sectional view of an X-ray sensing device 20 in accordance with some embodiments of the present disclosure. The difference between the embodiment shown in FIG. 2 and the embodiment shown in FIG. 1 is that the X-ray sensing device 20 does not have the photoelectric sensing element 104. It should be understood that the same or similar components or elements in above and below contexts are represented by the same or similar reference numerals. The materials, manufacturing methods and functions of these components or elements are the same or similar to those described above, and thus will not be repeated herein.

As shown in FIG. 2, the columnar structure 114 of the X-ray sensing device 20 is disposed over the circuit element 106, and the columnar structure 114 is in contact with the circuit element 106. Specifically, the columnar structure 114 is in direct contact with the circuit element 106. The scintillator material 112 of the columnar structure 114 is in contact with the circuit element 106. The columnar structure 114 extends from the top surface 102a of the first material layer 102 to the top surface of the circuit element 106 in accordance with some embodiments. As described above, the scintillator material 112 is formed of X-ray conversion materials that can convert X-rays into visible light or form electron-hole pairs. In this embodiment, the scintillation material 112 directly converts the received X-ray photons into electron-hole pairs, and the circuit element 106 that is coupled to the columnar structure 114 is then converted into electronic signals. Specifically, the electron-hole pairs are respectively collected by the biased upper and lower electrodes (not illustrated) of the columnar structure 114, and then are converted into electronic signals such as current signals or voltage signals. The electrodes described above may also be regarded as a part of the circuit element 106. The generated electronic signals may be processed by the circuit element 106, and the electronic signals may be converted into digital images.

As described above, the X-ray sensing device 20 as shown in FIG. 2 can be regarded as a direct conversion type X-ray sensing device, which does not include the photoelectric sensing element 104. The electronic signals are directly received, processed and read by the circuit element 106 to generate digital images. In this embodiment, the scintillator material 112 includes perovskite, PbI₃, PbI₂, MgI₃, HgI₂, amorphous selenium (Se), CdTe, SiO₂ or a combination thereof.

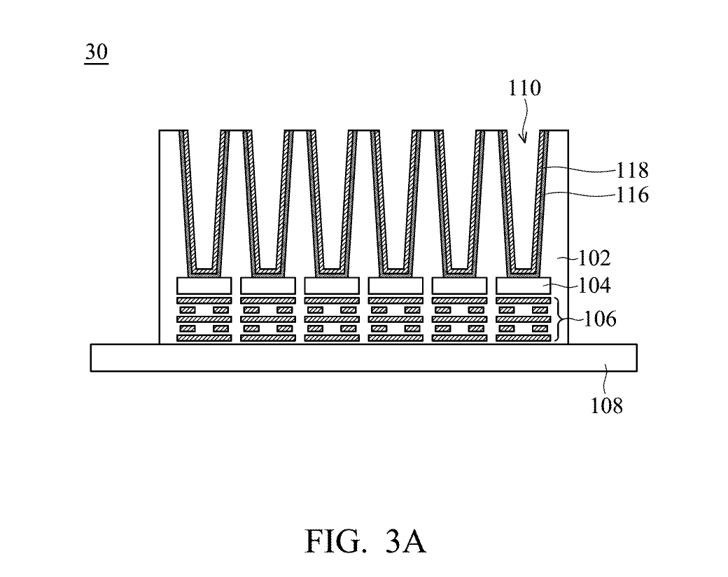

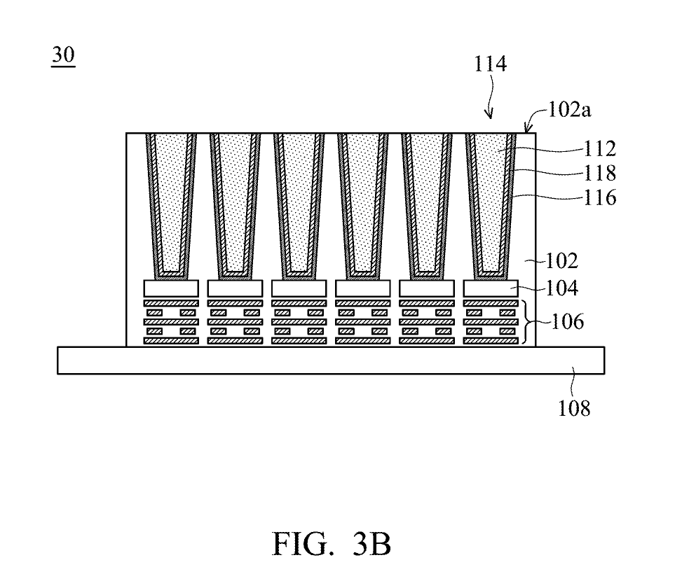

Next, refer to FIGS. 3A and 3B, which are cross-sectional views of an X-ray sensing device 30 in the intermediate stages of the process for manufacturing the X-ray sensing device in accordance with other embodiments of the present disclosure. The process stages shown in FIGS. 3A and 3B may follow the steps shown in FIG. 1C above. As shown in FIG. 3A, after the patterning process is performed to form the opening 110, a dielectric layer 116 is formed in the opening 110. The dielectric layer 116 is conformally formed in the opening 110 in accordance with some embodiments. The dielectric layer 116 is formed of dielectric materials. In some embodiment, the dielectric materials may include silicon oxide, silicon nitride, silicon oxynitride, silicon carbide, aluminum oxide, any other applicable dielectric material, or a combination thereof. In some embodiments, the dielectric layer 116 may be formed by a chemical vapor deposition process, a physical vapor deposition process, an atomic layer deposition (ALD), a spin coating process, any other applicable process, or a combination thereof.

Next, a conductive layer 118 is formed over the dielectric layer 116. The conductive layer 118 may be formed of conductive materials. In some embodiments, the conductive material may include copper (Cu), aluminum (Al), molybdenum (Mo), tungsten (W), gold (Au), chromium (Cr), nickel (Ni), platinum (Pt), titanium (Ti), iridium (Ir), rhodium (Rh), copper alloys, aluminum alloys, molybdenum alloys, tungsten alloys, gold alloys, chromium alloys, nickel alloys, platinum alloys, titanium alloys, iridium alloys, rhodium alloys, any other applicable conductive material, or a combination thereof. In some embodiments, the conductive layer 118 may be formed by a chemical vapor deposition (CVD) process, a physical vapor deposition (PVD) process, an electroplating process, an electroless plating process, any other applicable process, or a combination thereof. The physical vapor deposition process may include a sputtering process, an evaporation process, or a pulsed laser deposition (PLD) process.

Next, referring to FIG. 3B, the scintillation material 112 is formed in the opening 110 and over the conductive layer 118 to form the columnar structure 114. The columnar structure 114 is correspondingly disposed over the photoelectric sensing element 104 and is in contact with the photoelectric sensing element 104. The columnar structure 114 of the X-ray sensing device 30 further includes the dielectric layer 116 and the conductive layer 118 as compared to the embodiment shown in FIG. 1D. The dielectric layer 116 is disposed between the conductive layer 118 and the first material layer 102. The conductive layer 118 is disposed between the scintillation material 112 and the dielectric layer 116. The dielectric layer 116 is in contact with the photoelectric sensing element 104 in accordance with some embodiments.

In this embodiment, since the columnar structure 114 has the conductive layer 118, the columnar structure 114 may also serve as a via to provide additional electrical connection to the columnar structure 114. In addition, the conductive layer 118 is also disposed aligned with the photoelectric sensing element 104, and has anti-scattering effect to prevent scattered X-rays from entering the X-ray sensing device. Therefore, the quality of the generated image may be further improved.

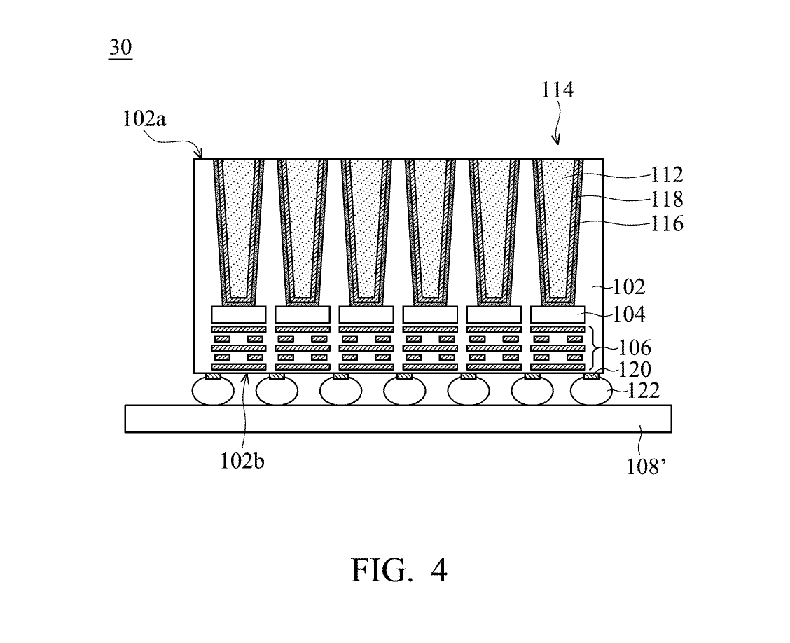

Next, referring to FIG. 4, FIG. 4 illustrates a diagram showing the electrical connection between an X-ray sensing device 30 and an external circuit in accordance with some embodiments of the present disclosure. As shown in FIG. 4, the X-ray sensing device 30 may further include a pad 120. The pad 120 may be disposed on the bottom surface 102b of the first material layer 102 and is coupled to the circuit element 106. The pad 120 is formed of conductive materials. In some embodiments, the conductive material may include copper (Cu), aluminum (Al), molybdenum (Mo), tungsten (W), gold (Au), chromium (Cr), nickel (Ni), platinum (Pt), titanium (Ti), iridium (Ir), rhodium (Rh), copper alloys, aluminum alloys, molybdenum alloys, tungsten alloys, gold alloys, chromium alloys, nickel alloys, platinum alloys, titanium alloys, iridium alloys, rhodium alloys, any other applicable conductive material, or a combination thereof.

Moreover, the pad 120 may be further coupled to an external circuit (not illustrated) through a solder ball 122 to electrically connect the X-ray sensing device 30 to the external circuit. The solder ball 122 is disposed below the circuit element 106, and is coupled to the circuit element 106 through the pad 120 disposed on the bottom surface 102b of the first material layer 102. The solder ball 122 may be formed of any suitable material. In some embodiments, the solder ball 122 may include tin (Sn), silver (Ag), copper (Cu), any other applicable material, or a combination thereof.

Furthermore, the solder ball 122 may be disposed over the substrate 108′ for the subsequent packaging processes of X-ray sensing device 30 in accordance with some embodiments. In some embodiments, the substrate 108′ may be a silicon substrate, a glass substrate, a polymer substrate, a polymer-based composite substrate, or a combination thereof, but it is not limited thereto. In some embodiments, the material of the substrate 108′ may include glass, quartz, sapphire, polycarbonate (PC), polyimide (PI), polyethylene terephthalate (PET), any other applicable material, or a combination thereof.

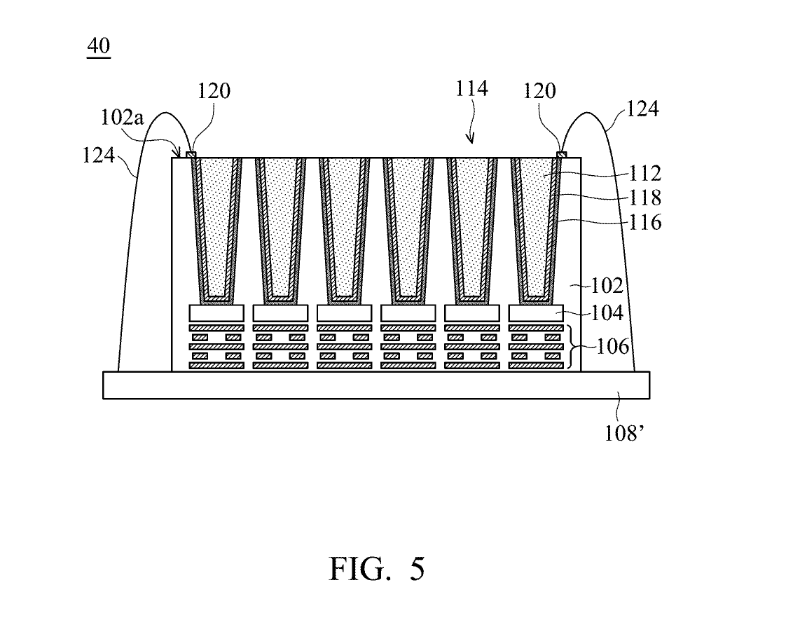

Next, referring to FIG. 5, FIG. 5 illustrates a diagram showing the electrical connection between an X-ray sensing device 40 and an external circuit in accordance with some embodiments of the present disclosure. As shown in FIG. 5, the pad 120 may be disposed on the top surface 102a of the first material layer 102, and the pad 120 may be coupled to the circuit element 106 through the conductive layer 118. In addition, the pad 120 may be further coupled to an external circuit (not illustrated) by wire bonding so that the X-ray sensing device 40 may be electrically connected to the external circuit. In some embodiments, the pad 120 may be coupled to an external circuit (not illustrated) through a bonding element 124 so that the X-ray sensing device 40 may be electrically connected to the external circuit. In some embodiments, the pad 120 may be electrically connected to the exterior elements disposed over the substrate 108′ through the bonding element 124, and the subsequent packaging processes may be carried out on the substrate 108′. The bonding element 124 may include bonding ball and bonding wire. In some embodiments, the material of the bonding element 124 may include gold (Au), copper (Cu), aluminum (Al), any other applicable material, or a combination thereof.

In addition, it should be understood that although the X-ray sensing devices shown in FIGS. 4 and 5 include several repeated units (e.g., several photoelectric sensing elements 104, circuit elements 106, columnar structures 112 and so on) and several repeated units are packaged together on the substrate 108′, the X-ray sensing device may also be packaged in the form of a single sensing unit 10′ (as shown in FIG. 1D) in accordance with some other embodiments. Specifically, in accordance with some embodiments, the carrier substrate 108 may be removed after the step shown in FIG. 1D, and a cutting process may be performed on the first material layer 102 to form a plurality of sensing units 10′ (dies) and the subsequent packaging processes may be performed.

To summarize the above, the X-ray sensing device provided in the embodiments of the present disclosure includes the columnar structure containing the scintillator materials. In such a configuration, the amount of scintillator materials can be saved, and the detective quantum efficiency and resolution of imaging of the X-ray sensing devices can be improved. In addition, in accordance with some embodiments of the present disclosure, the X-ray sensing device is fabricated by simple semiconductor processes, and the fabricated columnar structure can be accurately aligned with the photoelectric sensing element or the circuit element. Accordingly, the process efficiency and product yield can be improved.

Furthermore, in accordance with some embodiments of the present disclosure, there is no need to use an adhesive layer to fix the elements (for example, the adhesive layer is not required to fix the photoelectric sensing element with the circuit element, or the adhesive layer is not required to fix the photoelectric sensing element with the columnar structure and so on). Therefore, the crosstalk interference of the signals may be reduced.

Although some embodiments of the present disclosure and their advantages have been described in detail, it should be understood that various changes, substitutions and alterations can be made herein without departing from the spirit and scope of the disclosure as defined by the appended claims. For example, it will be readily understood by one of ordinary skill in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An X-ray sensing device, comprising:
a substrate;
a first material layer disposed over the substrate;
a circuit element disposed at a bottom portion of the first material layer;
a photoelectric sensing element disposed over the circuit element;
a columnar structure correspondingly disposed over the photoelectric sensing element and contacting the photoelectric sensing element, wherein the columnar structure comprises a scintillator material; and
a pad disposed on a top surface or a bottom surface of the first material layer and coupled to the circuit element.

2. The X-ray sensing device as claimed in claim 1, wherein the scintillator material is in contact with the photoelectric sensing element.

3. The X-ray sensing device as claimed in claim 1, further comprising a dielectric layer and a conductive layer, wherein the dielectric layer is disposed between the conductive layer and the first material layer, and the conductive layer is disposed between the scintillator material and the dielectric layer.

4. The X-ray sensing device as claimed in claim 1, wherein the scintillator material comprises CsI:Tl, CsI:Na, CsI, BGO(B₄G₃O₁₂), LYSO, YSO, Cd₂O₂S:Tb or a combination thereof.

5. The X-ray sensing device as claimed in claim 1, wherein the aspect ratio of the columnar structure is in a range from 1:1 to 2.1.

6. The X-ray sensing device as claimed in claim 1, wherein the circuit element comprises an analog-to-digital converter, an image signal processor or a combination thereof.

7. The X-ray sensing device as claimed in claim 1, further comprising a second material layer disposed over the first material layer, and the second material layer comprising tantalum oxides (TaO₂), copper (Cu), aluminum (Al) or a combination thereof.

8. The X-ray sensing device as claimed in claim 1, wherein the columnar structure extends from the top surface of the first material layer to a top surface of the photoelectric sensing element.

9. The X-ray sensing device as claimed in claim 1, further comprising a solder ball disposed below the circuit element, wherein the solder ball is coupled to the circuit element through the pad disposed on the bottom surface of the first material layer.

10. The X-ray sensing device as claimed in claim 1, further comprising a bonding element coupled to the pad disposed on the top surface of the first material layer.

11. An X-ray sensing device, comprising:
a substrate;
a first material layer disposed over the substrate;
a circuit element disposed at a bottom portion of the first material layer;
a columnar structure disposed over the circuit element and contacting the circuit element, wherein the columnar structure comprises a scintillator material; and
a pad disposed on a top surface or a bottom surface of the first material layer and coupled to the circuit element.

12. The X-ray sensing device as claimed in claim 11, wherein the scintillator material comprises perovskite, PbI₃, PbI₂, MgI₃, HgI₂, amorphous selenium (Se), CdTe, SiO₂ or a combination thereof.

13. The X-ray sensing device as claimed in claim 11, wherein the first material layer comprises silicon (Si) or glass.

14. The X-ray sensing device as claimed in claim 11, wherein the aspect ratio of the columnar structure is in a range from 1:1 to 2.1.

15. The X-ray sensing device as claimed in claim 11, wherein the columnar structure is a via.

16. The X-ray sensing device as claimed in claim 11, wherein the circuit element comprises an analog-to-digital converter, an image signal processor or a combination thereof.

17. The X-ray sensing device as claimed in claim 11, wherein the columnar structure extends from the top surface of the first material layer to a top surface of the circuit element.

18. A method for manufacturing an X-ray sensing device, comprising:
providing a carrier substrate;
forming a first material layer over the substrate, wherein a circuit element is disposed at a bottom portion of the first material layer, and wherein a photoelectric sensing element is disposed over the circuit element;
patterning the first material layer to form an opening that exposes a portion of the surface of the photoelectric sensing element; and
filling a scintillator material in the opening to form a columnar structure, wherein the columnar structure is in contact with the photoelectric sensing element.

19. The method for manufacturing an X-ray sensing device as claimed in claim 18, wherein prior to filling the scintillator material in the opening, the method further comprises:
forming a dielectric layer in the opening; and
forming a conductive layer over the dielectric layer.

20. The method for manufacturing an X-ray sensing device as claimed in claim 18, further comprising:
forming a second material layer over the first material layer.
